(19) United States
(12) Patent Application Publication
(10) Pub. No.: US 2014/0159184 A1
(43) Pub. Date: Jun. 12, 2014

(54) IMAGE SENSOR AND METHOD FOR FABRICATING THE SAME

(71) Applicant: SK HYNIX INC., Gyeonggi-do (KR)

(72) Inventor: Youn-Sub LIM, Gyeonggi-do (KR)

(73) Assignee: SK HYNIX INC., Gyeonggi-do (KR)

(21) Appl. No.: 13/828,621

(22) Filed: Mar. 14, 2013

(30) Foreign Application Priority Data
Dec. 11, 2012 (KR) 10-2012-0143246

(51) Int. Cl. H01L 27/146

(52) U.S. Cl. CPC H01L 27/14621
USPC 257/432; 438/70

(57) ABSTRACT

An image sensor includes a substrate including a plurality of unit pixel regions, a color filter formed over the substrate so as to correspond to each of the unit pixel regions, and a light absorption unit formed in the substrate under the color filter.

### CROSS-REFERENCE TO RELATED APPLICATIONS

The present application claims priority of Korean Patent Application No. 10-2012-0143246, filed on Dec. 11, 2012, which is incorporated herein by reference in its entirety.

### BACKGROUND

1. Field

Exemplary embodiments of the present invention relate to a semiconductor device fabrication technology, and more particularly, to an image sensor and a method for fabricating the same.

2. Description of the Related Art

A conventional CMOS image sensor is fabricated by the following process: forming a plurality of transistors over a substrate having a photodiode formed for each pixel, forming a multilayer of metal interconnections and a plurality of interlayer dielectric layers over the transistors, and forming a plurality of color filters and a plurality of micro lenses over the interlayer dielectric layers.

In the conventional CMOS image sensor having the structure fabricated by the above-described process, light is significantly influenced by the metal interconnections until the light reaches the photodiode from the micro lens. Therefore, the photosensitivity and quantum efficiency of the image sensor may decrease. In order to solve such a concern, a backside illumination image sensor receiving light through a backside B thereof has been proposed.

FIG. 1 is a diagram illustrating a conventional backside illumination image sensor.

Referring to FIG. 1, an interlayer dielectric layer 13 including metal interconnections 14 is positioned on a frontside F of a substrate 11 having unit pixel regions 101, 102, and 103 each including an isolation layer (not illustrated) and a light receiving element 12. Furthermore, an anti-reflection layer 15 is formed on a backside B of the substrate 11.

Color filters 16 corresponding to the respective unit pixel regions 101, 102, and 103 are formed over the anti-reflection layer 15. A planarized layer 17 is positioned over the color filters 16. A micro lens 18 is formed over the planarized layer 17 so as to correspond to each of the unit pixel regions 101, 102, and 103.

The backside illumination image sensor structure may exclude an effect of the metal interconnections, and may improve photosensitivity because the structure has no interlayer dielectric layer. However, since the isolation layer formed by a shallow trench isolation (STI) process and a plurality of photodiodes formed by an ion implant process may not reliably isolated from each other, the improvement of optical crosstalk (X-talk) characteristic may be limited, and the reduction of quantum efficiency (QE) may accompanied.

### SUMMARY

Various exemplary embodiments of the present invention are directed to an image sensor that may prevent optical crosstalk and simultaneously increase quantum efficiency, and a method for fabricating the same.

In an exemplary embodiment of the present invention, an image sensor includes a substrate including a plurality of unit pixel regions; a color filter formed over the substrate so as to correspond to each of the unit pixel regions; and a light absorption unit formed in the substrate under the color filter.

In another exemplary embodiment of the present invention, an image sensor includes a substrate including a plurality of unit pixel regions; a color filter formed over the substrate; and a light absorption unit formed in the substrate under the color filter, wherein the color filter includes a first color filter, a second color filter, and a third color filter, and the first color filter overlaps the light absorption unit.

In still another exemplary embodiment of the present invention, an image sensor includes a substrate including a plurality of unit pixel regions; a color filter having a multilayer structure over the substrate; and a light absorption unit formed in the substrate under the color filter, wherein the color filter includes a first color filter, a second color filter, and a third color filter, and the first to third color filters overlap the light absorption unit.

In still another exemplary embodiment of the present invention, a method for fabricating an image sensor includes forming a substrate including a plurality of unit pixel regions; forming a light absorption unit in the substrate along the boundary between the unit pixel regions; and forming a color filter over the substrate so as to correspond to each of the unit pixel regions, wherein the color filter includes a first color filter, a second color filter, and a third color filter.

### BRIEF DESCRIPTION OF THE DRAWINGS

FIG. 1 is a diagram illustrating a conventional backside illumination image sensor.

FIG. 2 is a cross-sectional view of an image sensor in accordance with a first embodiment of the present invention.

FIG. 3 is a plan view of a color filter and a light absorption unit of the image sensor in accordance with the first embodiment of the present invention.

FIGS. 4A and 4B are graphs showing transmittances of color filter materials for each wavelength.

FIGS. 5A to 5H are cross-sectional views illustrating a method for fabricating the image sensor in accordance with the first embodiment of the present invention.

FIG. 6 is a cross-sectional view of an image sensor in accordance with a second embodiment of the present invention.

FIG. 7 is a cross-sectional view of an image sensor in accordance with a third embodiment of the present invention.

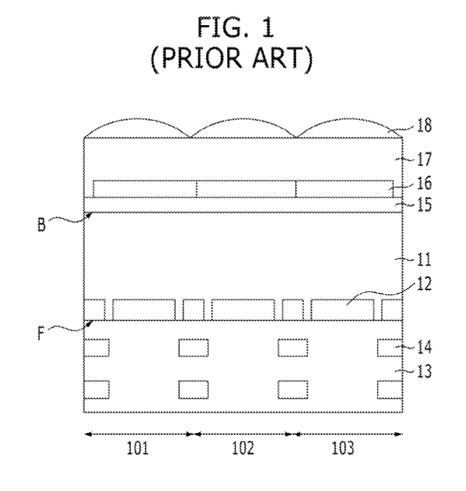

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and in some instances, proportions may have been exaggerated in order to clearly illustrate features of the embodiments. When a first layer is referred to as being “on” a second layer or “on” a substrate, it not only refers to a case where the first layer is formed directly on the second layer or the substrate but also a case where a third layer exists between the first layer and the second layer or the substrate.

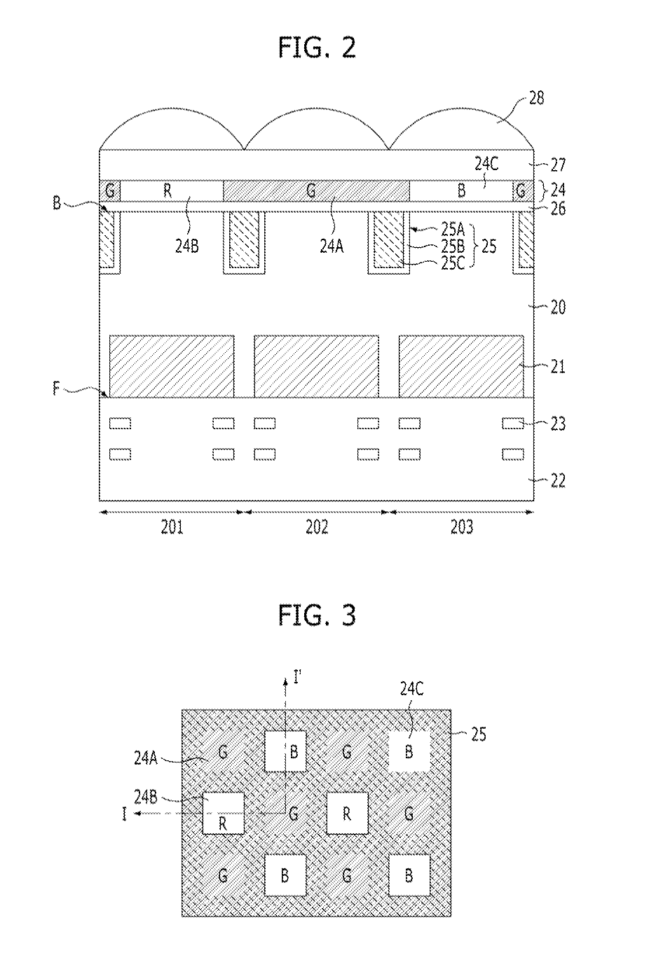

FIG. 2 is a cross-sectional view of an image sensor in accordance with a first embodiment of the present invention.

Referring to FIG. 2, an image sensor in accordance with the first embodiment of the present invention may include a substrate 20, a light receiving element 21, an interlayer dielectric layer 22, a color filter 24, a light absorption unit 25, an anti-reflection layer 26, a planarized layer 27, and a micro lens 28. The substrate 20 has a plurality of unit pixel regions 201, 202, and 203. The light receiving element 21 is formed in each of the unit pixel regions 201, 202, and 203 of the substrate 20. The interlayer dielectric layer 22 is formed on a frontside F of the substrate 20 and includes a signal generation circuit 23. The color filter 24 is formed over a backside B of the substrate 20, corresponding to the opposite side of the frontside F. The light absorption unit 25 is formed in the backside B of the substrate 20, under the color filter 24. The anti-reflection layer 26 is formed on the backside B of the substrate 20, under the color filter 24. The planarized layer 27 is formed over the backside B of the substrate 20 so as to cover the color filter 24. The micro lens 28 is formed over the planarized layer 27 so as to correspond to each of the unit pixel regions 201, 202, and 203.

The light receiving element 21 formed in each of the unit pixel regions 201, 202, and 203 of the substrate may include a photodiode. The photodiode serves to generate photo-charges using received light.

The interlayer dielectric layer 22 is formed on the frontside F of the substrate 20, and the signal generation circuit 23 is formed in the interlayer dielectric layer 22. The signal generation circuit 23 serves to generate an electrical signal corresponding to the photo-charges generated by the light receiving element 21. Specifically, the interlayer dielectric layer 22 formed on the frontside F of the substrate 20 may include a plurality of transistors and a multilayer of conductive lines, which form the signal generation circuit 23. The transistors may include a transfer transistor, a reset transistor, a source follower transistor, a select transistor, and a bias transistor. Furthermore, the multilayer of conductive lines may be electrically connected to the transistors, directly or indirectly through plugs.

The color filter 24 is formed over the backside B of the substrate 20. The color filter 24 may be formed to correspond to each of the unit pixel regions 201, 202, and 203. The color filter 24 may include a plurality of first color filters 24A, a plurality of second color filters 24B, and a plurality of third color filters 24C. The color filter 24 may have an RGB structure. For example, the first color filter 24A may include a green color filter, the second color filter 24B may include a red color filter, and the third color filter 24C may include a blue color filter. The first color filter 24A may have a structure overlapping the light absorption unit 25.

The light absorption unit 25 is formed in the backside B of the substrate 20, under the color filter 24. Specifically, the light absorption unit 25 is formed between the respective unit pixel regions 201, 202, and 203, and may have a structure overlapping the first color filter 24A. The light absorption unit 25 may include a trench 25A formed in the substrate 20, an interface layer 25B formed on the surface of the trench 25A, and a light absorbing material layer 25C formed on the interface layer 25B so as to fill the trench 25A. The light absorption unit 25 serves to prevent an optical crosstalk between the adjacent unit pixel regions and simultaneously increase quantum efficiency.

The trench 25A may be formed along the boundary between the respective unit pixel regions 201, 202, and 203 in the backside B of the substrate 20. The trench 25A may have a smaller critical dimension (CD) than those of the unit pixel regions 201, 202, and 203. Specifically, the trench 25A may have a CD of 0.05 to 0.2 μm. Furthermore, the depth of the trench 25A is larger than the CD thereof, and the trench 25A may be formed to be contacted with an isolation layer (not illustrated) formed in the frontside F of the substrate 20. The trench 25A may have a depth of 0.3 to 0.5 μm.

The interface layer 25B may serve to improve an interface characteristic between the light absorption layer 25C and the surface of the trench 25A formed in the backside B of the substrate 20, and simultaneously perform an anti-reflection function. The interface layer 25B may include an insulating material. For example, the interface layer 25B may include any one single layer selected from the group consisting of an oxide layer, a nitride layer, or an oxynitride layer, or a stacked layer thereof. For example, the interface layer 25B may be formed of oxide.

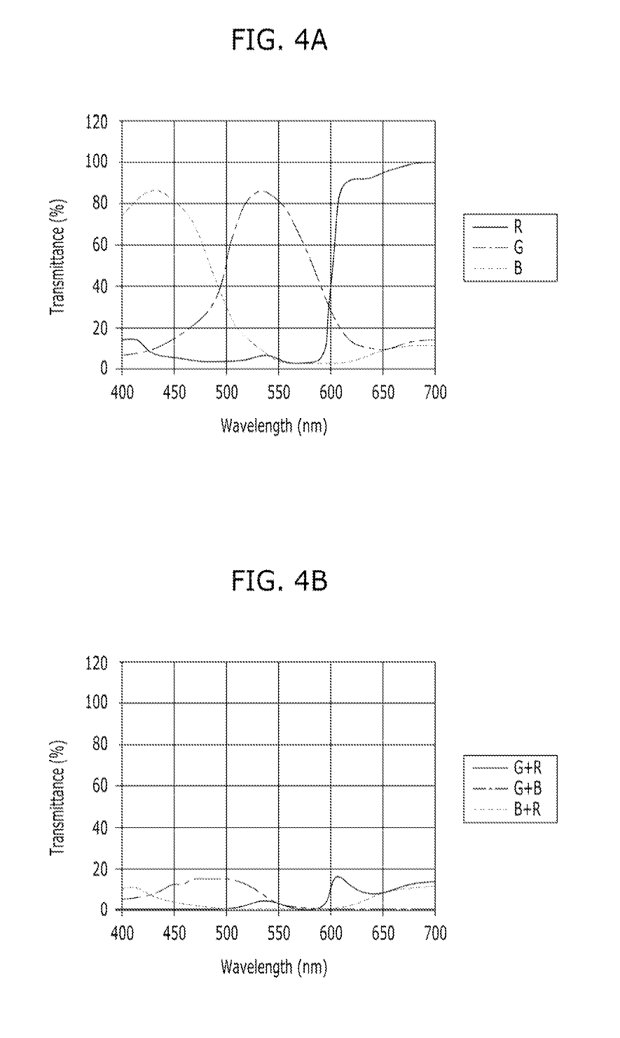

The light absorbing material layer 25C may include any materials that may absorb visible light. In the first embodiment of the present invention, a color filter material may be used as the light absorbing material layer 25C. Specifically, the color filter material may include a red color filter material, a green color filter material, and a blue color filter material. For example, when the light absorption unit 25 overlaps the green color filter, a red color filter material or a blue color filter material may be used as the light absorbing material layer 25C. For example, the light absorbing material layer 25C may include a blue color filter material, in order to effectively prevent optical crosstalk between the adjacent unit pixel regions. The reason to use a blue color filter material as the light absorbing material layer 25C will be described below with reference to FIGS. 4A and 4B, which are graphs showing transmittances based on the wavelengths of color filter materials.

The anti-reflection layer 26 is formed on the backside B of the substrate 20 including the light absorption unit 25, under the color filter. As such, when the anti-reflection layer 26 is formed between the color filter 24 and the substrate 20 including the light absorption unit 25, the color filter 24 and the light absorption unit 25 may prevent optical crosstalk more effectively.

The planarized layer 27 is formed over the substrate 20 so as to cover the color filter 24. The micro lens 28 is formed over the planarized layer 27 so as to correspond to each of the unit pixel regions 201, 202, and 203 and the color filter 24. The micro lens 28 is formed in a hemispherical shape over the planarized layer 27 so as to correspond to each of the unit pixel regions 201, 202, and 203, and serves to condense light into each of the unit pixel regions 201, 202, and 203.

Since the image sensor having the above-described structure includes the light absorption unit 25, it is possible to prevent optical crosstalk between the adjacent unit pixel regions 201, 202, and 203 and simultaneously increase quantum efficiency.

Furthermore, since the light absorption unit 25 has a structure overlapping the color filter 24, it is possible to prevent optical crosstalk between the adjacent unit pixel regions 201, 202, and 203 effectively and simultaneously increase quantum efficiency effectively.

Furthermore, since the light absorption unit 25 overlaps the green color filter and includes a blue color filter material, it is possible to prevent optical crosstalk between the adjacent unit pixel regions 201, 202, and 203 more effectively and simultaneously increase quantum efficiency more effectively.

FIG. 3 is a plan view of the color filter and the light absorption unit of the image sensor in accordance with the first embodiment of the present invention. The cross-sectional view of FIG. 2 is taken along I-I′ line of FIG. 3.

Referring to FIG. 3, the color filter 24 may include a plurality of first color filters 24A, a plurality of second color filters 24B, and a plurality of third color filters 24C. The color filter 24 may have an RGB structure. The color filter 24 may include a plurality of red color filters, green color filters, and blue color filters. For example, the first color filter 24A may include a green color filter, the second color filter 24B may include a red color filter, and the third color filter 24C may include a blue color filter. For example, the first color filter 24A may be arranged to overlap the light absorption unit. Since the first color filter 24A is formed to overlap the light absorption unit, the first color filter 24A may have a larger area than those of the second and third color filters 24B and 24C. Specifically, as the first color filter 24A is arranged to overlap the light absorption unit, the first color filter 24A may have a large area. As the area of the first color filter 24A is increased, the second and third color filters 24B and 24C may have a small area.

FIGS. 4A and 4B are graphs showing transmittances of color filter materials for each wavelength. FIG. 4A is a graph showing transmittance of a single color filter material for each wavelength, and FIG. 4B is a graph showing transmittance of double color filter materials for each wavelength.

FIG. 4A shows transmittance based on the wavelength of light incident on each unit pixel region. As shown, when the light incident on the unit pixel region passes through a single color filter material, the single color filter material has a high transmittance overall.

FIG. 4B shows transmittance based on the wavelength of double color filter materials. As shown, when incident light passes through the double color filter materials, the double color filter materials have a lower transmittance than that of the single color filter material, obtained when the incident light passes through a single color filter material. Specifically, in FIG. 4B, the transmittance based on the wavelength of green color filter material-blue color filter material is lower than those of the transmittance based on the wavelength of green color filter material-red color filter material or the transmittance based on the wavelength of blue color filter material-red color filter material. As such, when the light absorption unit in accordance with the first embodiment of the present invention has a structure overlapping the green color filter, the blue color filter material having a lower transmittance than that of the red color filter material may be used to form the light absorption unit. In this case, optical crosstalk may be prevented more effectively.

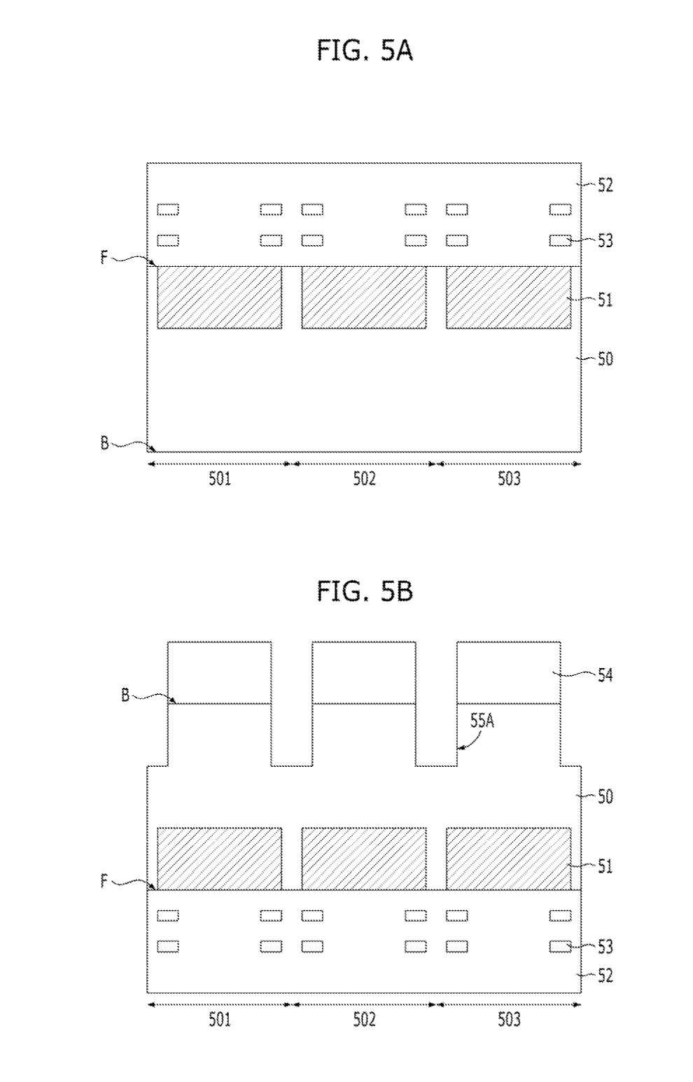

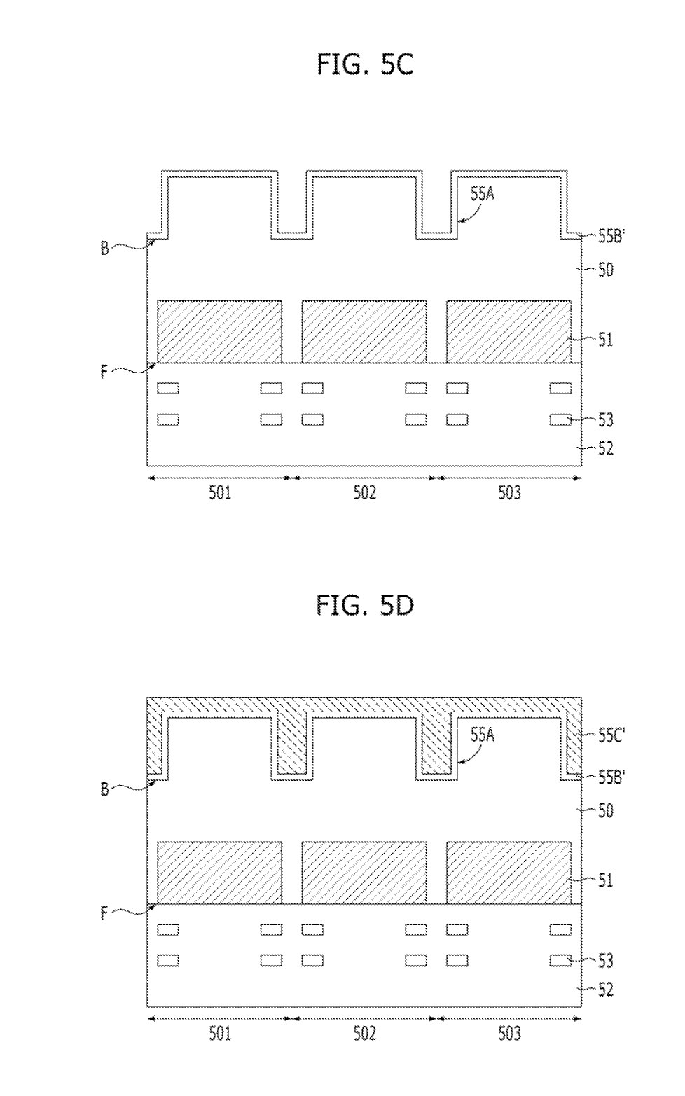

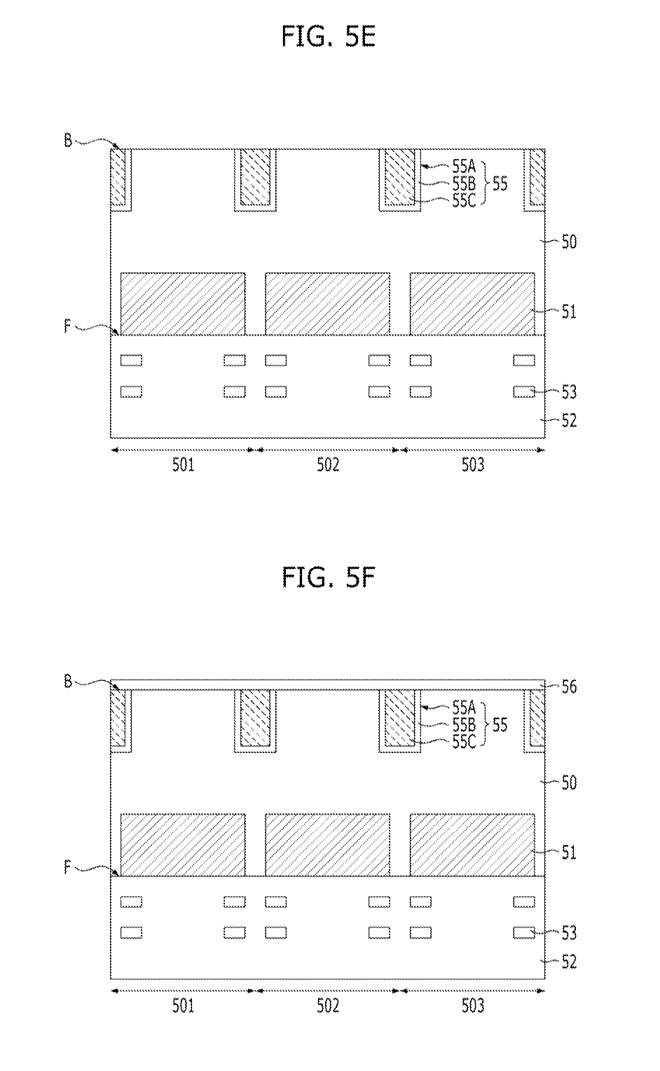

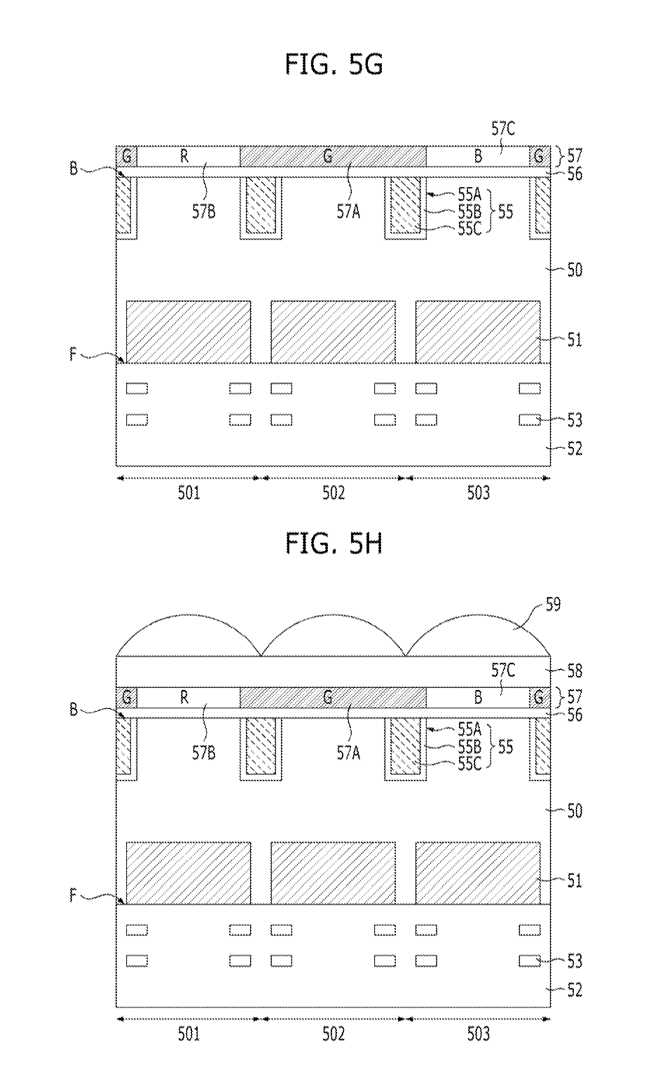

FIGS. 5A to 5H are cross-sectional views illustrating a method for fabricating the image sensor in accordance with the first embodiment of the present invention.

Referring to FIG. 5A, a substrate 50 having a plurality of unit pixel regions 501, 502, and 503 is prepared. The substrate 50 may include a single crystalline material. Furthermore, the substrate 50 may include a silicon containing material. Therefore, the substrate 50 may include single crystalline silicon.

Then, an isolation layer (not illustrated) is formed in the frontside F of the substrate 50 so as to isolate a light receiving element to be formed by a subsequent process from another adjacent light receiving element. The isolation layer may be formed by an STI process. Furthermore, a light receiving element 51 is formed in the frontside F of the substrate 50 so as to correspond to each of the unit pixel regions 501, 502, and 503. The light receiving element 51 may include a photodiode.

Then, an interlayer dielectric layer 52 including a signal generation circuit 53 is formed on the frontside F of the substrate 50 including the light receiving element 51. The signal generation circuit 53 may include a plurality of transistors and a multilayer of conductive lines.

Referring to FIG. 5B, a grinding process is performed on the backside B of the substrate 50. The grinding process may reduce a propagation path of light incident on the light receiving element 51 through the backside B of the substrate 50, thereby increasing condensing efficiency.

Then, a backside treatment is performed to cure a defect of the backside B of the substrate 50, which is caused by the grinding process. The backside treatment may be performed through a heat treatment under an oxygen atmosphere.

Then, a mask pattern 54 is formed on the backside B of the substrate 50. Using the mask pattern 54 as an etch barrier, the backside B of the substrate 50 is etched to form a trench 55A. The etch process for forming the trench 55A may include an anisotropic etch process. The trench 55A may be formed along the boundary between the respective unit pixel regions 501, 502, and 503 in the backside B of the substrate 50. The trench 55A may have a smaller CD than those of the unit pixel regions 501, 502, and 503. The trench 55A may have a CD of 0.05 to 0.2 μm. Furthermore, the CD of the trench 55A is larger than the depth thereof, and the trench 55A may be formed to be contacted with the isolation layer (not illustrated) formed in the frontside F of the substrate 50. The trench 55A may have a depth of 0.3 to 0.5 μm.

Referring to FIG. 5C, a mask pattern 54 is removed.

Then, an interface layer 55B′ is formed along the surface of the structure including the trench 55A. The interface layer 55B′ may serve to improve the interface characteristic between a light absorbing material layer 55C′ and the surface of the trench 55A formed in the backside B of the substrate 50, and perform an anti-reflection function. The interface layer 55B′ may include an insulating material. For example, the interface layer 55B′ may include any one single layer selected from the group consisting of an oxide layer, a nitride layer, or an oxynitride layer, or a stacked layer thereof. For example, the interface layer 55B′ may be formed of oxide.

Referring to FIG. 5D, the light absorbing material layer 55C′ is formed over the interface layer 55B′ so as to gap-fill the trench 55A. The light absorbing material layer 55C′ may include any materials as long as they can absorb visible light. In the first embodiment of the present invention, a color filter material may be used as the light absorbing material layer 55C′. Specifically, the color filter material may include a red color filter material, a green color filter material, or a blue color filter material. For example, when the light absorption unit 55 overlaps a green color filter formed by a subsequent process, the light absorbing material layer 55C′ may include a red color filter material or blue color filter material. For example, the blue color filter material may be used as the light absorbing material layer 55C′. The reason to use the blue color filter material as the light absorbing material layer 55C′ is that the transmittance thereof is much lower than that of the red color filter material, obtained when the light absorbing material layer 55C′ is formed of the red color filter material. In virtue of the foregoing features, it may be possible to prevent optical crosstalk between adjacent unit pixels.

Referring to FIG. 5E, a planarizing process is performed on the light absorbing material layer 55C′ and the interface layer 55B′ until the surface of the substrate 50 is exposed, thereby forming a light absorption unit 55. The planarizing process may include a chemical mechanical polishing (CMP) process or etch-back process.

Accordingly, the light absorption unit 55 including the trench 55A, an interface layer pattern 558, and a light absorbing material layer pattern 55C may be formed.

Referring to FIG. 5F, an anti-reflection layer 56 is formed on the backside B of the substrate 50. Since the anti-reflection layer 56 hardly reflects light, the light absorption unit 55 and a color filter 57 to be formed by a subsequent process may prevent crosstalk more effectively through the anti-reflection layer 56.

Referring to FIG. 5G, the color filter 57 corresponding to the light receiving element 51 is formed over the anti-reflection layer 56. The color filter 57 may include a plurality of first color filters 57A, a plurality of second color filters 57B, and a plurality of third color filters 57C. The color filter 57 may have an RGB structure. For example, the first color filter 57A may include a green color filter, the second color filter 57B may include a red color filter, and the third color filter 57C may include a blue color filter. The first color filter 57A may have a structure overlapping the light absorption unit 55. The first color filter 57A overlapping the light absorption unit 55 may have a larger CD than that of each of the unit pixel regions 501, 502, and 503, and the second and third color filters 57B and 57C may have a smaller CD than that of the unit pixel region. An existing color filter is formed to have a CD corresponding to each unit pixel. In accordance with the first embodiment of the present invention, however, the first color filter 57A may have a larger CD than that of the existing color filter, because the first color filter 57A is formed to overlap the light absorption unit 55. Furthermore, as the CD of the first color filter 57A is increased, the second and third color filter 57B and 57C may have a small CD.

Referring to FIG. 5H, a planarized layer 58 is formed over the backside B of the substrate 50 so as to cover the color filter 57. Furthermore, a micro lens 59 is formed over the planarized layer 58 so as to correspond to each of the unit pixel regions 501, 502, and 503 and the color filter 57. The micro lens 59 is formed in a hemispherical shape over the planarized layer 58 so as to correspond to each of the unit pixel regions 501, 502, and 503, and may condense light into the unit pixel region.

Since the image sensor formed by the above-described fabrication method includes the light absorption unit 55, the image sensor may prevent optical crosstalk between the adjacent unit pixel regions 501, 502, and 503 and simultaneously increase quantum efficiency.

Furthermore, since the light absorption unit 55 and the color filter 57 are formed to overlap each other, it is possible to prevent optical crosstalk between the adjacent unit pixel regions 501, 502, and 503 effectively and simultaneously increase quantum efficiency effectively.

Furthermore, since the light absorption unit 55 including a blue color filter material is formed to overlap the green color filter, it is possible to prevent optical crosstalk between the adjacent unit pixel regions 501, 502, and 503 more effectively and increase quantum efficiency more effectively.

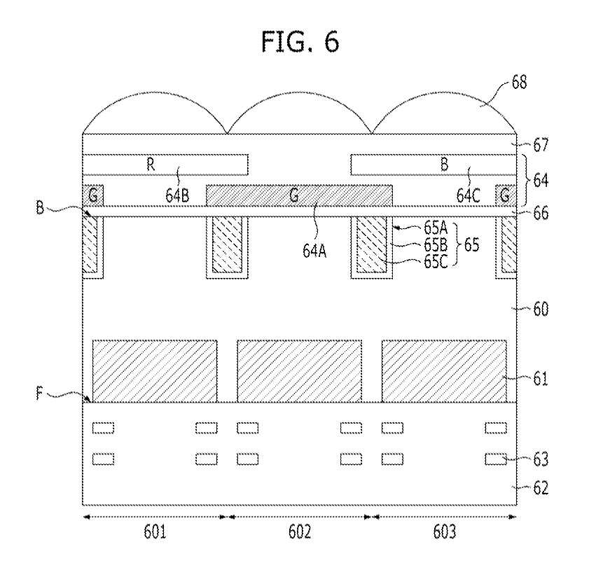

FIG. 6 is a cross-sectional view of an image sensor in accordance with a second embodiment of the present invention.

Referring to FIG. 6, an image sensor in accordance with the second embodiment of the present invention may include a substrate 60, a light receiving element 61, an interlayer dielectric layer 62, a color filter 64, a light absorption unit 65, an anti-reflection layer 66, a planarized layer 67, and a micro lens 68. The substrate 60 has a plurality of unit pixel regions 601, 602, and 603. The light receiving element 61 is formed in each of the unit pixel regions 601, 602, and 603 of the substrate. The interlayer dielectric layer 62 is formed on a frontside F of the substrate 60 and includes a signal generation circuit 63. The color filter 64 is formed over a backside B of the substrate 60, corresponding to the opposite side of the frontside F. The light absorption unit 65 is formed between unit pixels in the backside B of the substrate 60 under the color filter 64. The anti-reflection layer 66 is formed on the backside B of the substrate 60 under the color filter 64. The planarized layer 67 is formed over the backside B of the substrate 60 so as to cover the color filter 64. The micro lens 68 is formed over the planarized layer 67 so as to correspond to each of the unit pixel regions 601, 602, and 603.

The light receiving element 61 formed in each of the unit pixel regions 601, 602, and 603 of the substrate 60 may include a photodiode. The photodiode serves to generate photo-charges using received light.

The interlayer dielectric layer 62 is formed on the front side of the substrate 60, and the signal generation circuit 63 is formed in the interlayer dielectric layer 62. The signal generation circuit 63 serves to generate an electrical signal corresponding to the photo-charges generated by the light receiving element 61. Specifically, the Interlayer dielectric layer 62 formed on the front side F of the substrate 60 may include a plurality of transistors and a multilayer of conductive lines, which form the signal generation circuit 63. The transistors may include a transfer transistor, a reset transistor, a source follower transistor, a select transistor, and a bias transistor. Furthermore, the multilayer of conductive lines may be electrically connected to the transistors, directly or indirectly through plugs.

The color filter 64 having a multilayer structure is formed over the backside B of the substrate 60. The color filter 64 may be formed to correspond to each of the unit pixel regions 601, 602, and 603. The color filters 64 may be arranged in such a manner that ends thereof overlap each other. The color filters 64 may include a plurality of first color filters 64A, a plurality of second color filters 64B, and a plurality of third color filters 64C. In particular, the color filters 64 in accordance with the second embodiment of the present invention may be alternately formed at upper and lower layers, and both ends of the color filter 64 formed at the lower layer may overlap ends of the color filters 64 formed at the upper layer, adjacent to the color filter 64 formed at the lower layer. The lower color filter 64 may include the first color filter 64A, and the upper color filters 64 may include the second and third color filters 64B and 64C.

The color filter 64 may have an RGB structure. For example, the first color filter 64A may include a green color filter, the second color filter 64B may include a red color filter, and the third color filter 64C may include a blue color filter. The first and second color filters 64A and 64B may have a structure overlapping the light absorption unit 64.

The light absorption unit 65 is formed in the backside B of the substrate 60 under the color filter 64. Specifically, the light absorption unit 65 is formed between the respective unit pixel regions 601, 602, and 603, and may have a structure overlapping the first to third color filters 64A to 64C. Specifically, the light absorption unit 65 has a first overlap structure overlapping a green color filter, and the first overlap structure has a second overlap structure overlapping a red color filter or blue color filter. Accordingly, optical crosstalk between the adjacent unit pixel regions 601, 602, and 603 may be prevented, and quantum efficiency may be increased.

The light absorption unit 65 may include a trench 65A formed in the substrate 60, an interface layer 65B formed on the surface of the trench 65A, and a light absorbing material layer 65C formed over the interface layer 65B so as to fill the trench 65A.

The trench 65A may be formed along the boundary between the respective unit pixel regions 601, 602, and 603 in the backside B of the substrate 60. The trench 65A may have a smaller CD than that of each of the unit pixel regions 601, 602, and 603. Specifically, the trench 65A may have a CD of 0.05 to 0.2 μm. Furthermore, the depth of the trench 65A is larger than the CD thereof, and the trench 65A may be formed to be contacted with an isolation layer (not illustrated) formed in the frontside F of the substrate 60. The trench 65A may have a depth of 0.3 to 0.5 μm.

The interface layer 65B may serve to improve an interface characteristic between the light absorbing material layer 65C and the surface of the trench 65A formed in the backside B of the substrate 60, and may perform an anti-reflection function. The interface layer 65B may include an insulating material. For example, the interface layer 65B may include any one single layer selected from the group consisting of an oxide layer, a nitride layer, or an oxynitride layer, or a stacked layer thereof. For example, the interface layer 65B may be formed of oxide.

The light absorbing material layer 65C may include any materials as long as they can absorb visible light. In the second embodiment of the present invention, a color filter material may be used as the light absorbing material layer 65C. Specifically, the color filter material may include a red color filter material, a green color filter material, and a blue color filter material. For example, when the light absorption unit 65 overlaps the green color filter, the light absorbing material layer 65C may include the red color filter material or blue color filter material. For example, the light absorbing material layer 65C may use a blue color filter material. The reason to use the blue color filter material as the light absorbing material layer 65C is that the blue color filter material prevents optical crosstalk between the adjacent unit pixels more effectively than the red color filter material.

The first to third color filters 64A to 64C formed over the substrate 60 so as to overlap the light absorption unit 65 may have a larger CD than that of the unit pixel region. Specifically, an existing color filter is formed to correspond to the CD of the unit pixel region. However, in accordance with the second embodiment of the present invention, the first to third color filters 64A to 64C may have a larger CD than that of the existing color filter, because the first to third color filters 64A to 64C are formed to overlap the light absorption unit 65.

The anti-reflection layer 66 is formed on the backside B of the substrate 60 including the light absorption unit 65. The anti-reflection layer 66 serves to prevent optical crosstalk more effectively through the color filter 64 and the light absorption unit 65.

The planarized layer 67 is formed over the substrate 60 so as to cover the color filter 64. The micro lens 68 is formed over the planarized layer 67 so as to correspond to each of the unit pixel regions 601, 602, and 603 and the color filter 64. The micro lens 68 is formed in a hemispherical shape over the planarized layer 67 so as to correspond to each of the unit pixel regions 601, 602, and 603, and serves to condense light into each of the unit pixel regions 601, 602, and 603.

Since the image sensor having the above-described structure includes the light absorption unit 65, the image sensor may prevent optical crosstalk between the adjacent unit pixel regions 601, 602, and 603 and simultaneously increase quantum efficiency.

Furthermore, the color filter 64 has a multilayer structure, and the ends of the respective color filters 64 overlap each other. Therefore, it may be possible to prevent optical crosstalk between the adjacent unit pixels and simultaneously increase quantum efficiency.

Furthermore, since the light absorption unit 65 has a structure overlapping the color filter 64 with a multilayer structure, it is possible to prevent optical crosstalk between the adjacent unit pixel regions 601, 602, and 603 and simultaneously increase quantum efficiency effectively.

Furthermore, the light absorption unit 65 including a blue color filter material has the first overlap structure overlapping a green color filter, and the first overlap structure has the second overlap structure overlapping a red color filter or blue color filter. Therefore, it is possible to prevent optical crosstalk between the adjacent unit pixel regions 601, 602, and 603 and simultaneously increase quantum efficiency more effectively.

Furthermore, the light absorption unit 65, which includes a blue color filter material and overlaps the green color filter, overlaps the red color filter or the blue color filter that overlap either end of the green color filter. Therefore, it is possible to prevent optical crosstalk between the adjacent unit pixels and simultaneously increase quantum efficiency more effectively.

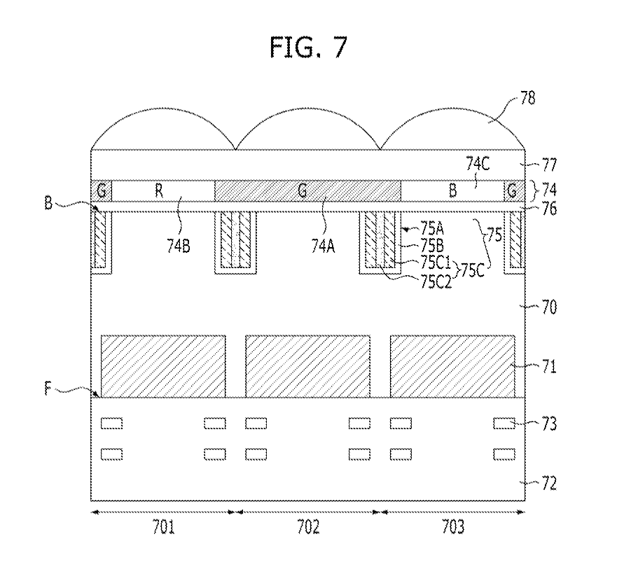

FIG. 7 is a cross-sectional view of an image sensor in accordance with a third embodiment of the present invention.

Referring to FIG. 7, an image sensor in accordance with the third embodiment of the present invention may include a substrate 70, a light receiving element 71, an interlayer dielectric layer 72, a color filter 74, a light absorption unit 75, an anti-reflection layer 76, a planarized layer 77, and a micro lens 78. The substrate 70 has a plurality of unit pixel regions 701, 702, and 703. The light receiving element 71 is formed in each of the unit pixel regions 701, 702, and 703 of the substrate 70. The interlayer dielectric layer 72 is formed on a frontside F of the substrate 70 and includes a signal generation circuit 73. The color filter 74 is formed over a backside B of the substrate 70, corresponding to the opposite side of the frontside F. The light absorption unit 65 is formed in the backside B of the substrate 70, corresponding to the opposite side of the frontside F. The anti-reflection layer 76 is formed between the respective unit pixels in the backside B of the substrate 70 under the color filter 74. The planarized layer 77 is formed over the backside B of the substrate 70 so as to cover the color filter 74. The micro lens 78 is formed over the planarized layer 77 so as to correspond to each of the unit pixel regions 701, 702, and 703.

The light receiving element 71 formed in each of the unit pixel regions 701, 702, and 703 of the substrate 70 may include a photodiode. The photodiode serves to generate photo-charges using received light.

The interlayer dielectric layer 72 is formed on the frontside F of the substrate 70, and the signal generation circuit 73 is formed in the interlayer dielectric layer 72. The signal generation circuit 73 serves to generate an electrical signal corresponding to the photo-charges generated by the light receiving element 71. Specifically, the interlayer dielectric layer 72 formed on the frontside F of the substrate 70 may include a plurality of transistors and a multilayer of conductive lines, which form the signal generation circuit 73. The transistors may include a transfer transistor, a reset transistor, a source follower transistor, a select transistor, and a bias transistor. Furthermore, the multilayer of conductive lines may be electrically connected to the transistors, directly or indirectly through plugs.

The color filter 74 is formed over the backside B of the substrate 70. The color filter 74 may be formed to correspond to each of the unit pixel regions 701, 702, and 703. The color filter 74 may include a plurality of first color filters 74A, a plurality of second color filters 74B, and a plurality of third color filters 74C. The color filter 74 may have an RGB structure. For example, the first color filter 74A may include a green color filter, the second color filter 74B may include a red color filter, and the third color filter 74C may include a blue color filter. The first color filter 74A may have a structure overlapping the light absorption unit 75.

The light absorption unit 75 is formed in the backside B of the substrate 70 under the color filter 74. Specifically, the light absorption unit 75 is formed between the respective unit pixel regions 701, 702, and 703, and may have a structure overlapping the first color filter 74A. The light absorption unit 75 may include a trench 75A formed in the substrate 70, an interface layer 75B formed on the surface of the trench 75A, and a light absorbing material layer 75C formed on the interface layer 75B so as to gap-fill the trench 75A. Accordingly, the light absorption unit 75 serves to prevent optical crosstalk between the adjacent unit pixel regions 701, 702, and 703 and simultaneously increase quantum efficiency.

The trench 75A may be formed along the boundary between the respective unit pixel regions 701, 702, and 703 in the backside B of the substrate 70. The trench 75A may have a smaller CD than that of each of the unit pixel regions 701, 702, and 703. Specifically, the trench 75A may have a CD of 0.05 to 0.2 μm. Furthermore, the depth of the trench 75A is larger than the CD thereof, and the trench 75A may be formed to be contacted with an isolation layer (not illustrated) formed in the frontside F of the substrate 70. The trench 75A may have a depth of 0.3 to 0.5 μm.

The interface layer 75B may serve to improve an interface characteristic between the light absorbing material layer 75C and the surface of the trench 75A formed in the backside B of the substrate 70, and may perform an anti-reflection function. The interface layer 75B may include an insulating material. For example, the interface layer 75B may include any one single layer selected from the group consisting of an oxide layer, a nitride layer, or an oxynitride layer, or a stacked layer thereof. For example, the interface layer 75B may be formed of oxide.

The light absorbing material layer 75C may include a first light absorbing material layer 75C1 formed on both sidewalls of the interface layer 75B and a second light absorbing material layer 75C2 formed on the first light absorbing material layer 75C1 so as to gap-fill the rest of the trench 75A.

The first and second light absorbing material layers 75C1 and 75C2 may include any materials as long as they can absorb visible light. In the third embodiment of the present invention, a color filter material may be used as the first and second light absorbing material layers 75C1 and 75C2. Specifically, the color filter material may include a red color filter material, a green color filter material, and a blue color filter material. For example, when the light absorption unit 75 overlaps the green color filter, the first and second light absorbing material layers 75C1 and 75C2 may include a red color filter material or blue color filter material. For example, the first light absorbing material layer 75C1 of the light absorbing material layer 75C may include a blue color filter material, and the second light absorbing material layer 75C2 may include a red color filter material, in order to prevent optical crosstalk between the adjacent unit pixels more effectively.

The first color filter 74A formed over the substrate 70 so as to overlap the light absorption unit 75 may have a larger CD than that of the unit pixel, and the second and third color filters 74B and 74C may have a smaller CD than that of the unit pixel. Specifically, an existing color filter is formed to correspond to the CD of the unit pixel. However, in accordance with the third embodiment of the present invention, the first color filter 74A may have a larger CD than that of the existing color filter, because the first color filter 74A is formed to overlap the light absorption unit 75. As the CD of the first color filter 74A is increased, the second and third color filters 74B and 74C may have a small CD.

The anti-reflection layer 76 is formed on the backside B of the substrate 70 including the light absorption unit 75. The anti-reflection layer 76 serves to prevent optical crosstalk more effectively through the color filter 74 and the light absorption unit 75.

The planarized layer 77 is formed over the substrate 70 so as to cover the color filter 74. The micro lens 78 is formed over the planarized layer 77 so as to correspond to each of the unit pixel regions 701, 702, and 703 and the color filter 74. The micro lens 78 is formed in a hemispherical shape over the planarized layer 77 so as to correspond to each of the unit pixel regions 701, 702, and 703, and serves to condense light into each of the unit pixel regions 701, 702, and 703.

Since the image sensor having the above-described structure includes the light absorption unit 75, the image sensor may prevent optical crosstalk between the adjacent unit pixel regions 701, 702, and 703 and increase quantum efficiency.

Furthermore, since the light absorption unit 75 has a structure overlapping the color filter 74, it may be possible to prevent optical crosstalk between the adjacent unit pixel regions 701, 702, and 703 and increase quantum efficiency effectively.

Furthermore, since the light absorption unit 75 including one or more light absorbing material layers 75C has a structure overlapping the color filter 74, it may be possible to prevent optical crosstalk between the adjacent unit pixel regions 701, 702, and 703 and increase quantum efficiency more effectively.

Furthermore, since the light absorption unit 75 including one or more light absorbing material layer 75C overlaps the green color filter and includes a blue color filter material and a red color filter material, it may be possible to prevent optical crosstalk between the adjacent unit pixel regions 701, 702, and 703 more effectively and simultaneously increase quantum efficiency more effectively.

Although various embodiments have been described for illustrative purposes, it will be apparent to those skilled in the art that various changes and modifications may be made without departing from the spirit and scope of the invention as defined in the following claims.

What is claimed is:

1. An image sensor comprising:
a substrate comprising a plurality of unit pixel regions;
a color filter formed over the substrate; and
a light absorption unit formed in the substrate under the color filter,
wherein the color filter comprises a first color filter, a second color filter, and a third color filter, and the first color filter overlaps the light absorption unit.

2. The image sensor of claim 1, wherein the color filter comprises a red color filter, a green color filter, and a blue color filter, and wherein the first color filter comprises the green color filter, the second color filter comprises the red color filter, and the third color filter comprises the blue color filter.

3. The image sensor of claim 1, wherein the first color filter has a larger critical dimension (CD) than that of the unit pixel region, and the second and third color filters have a smaller CD than that of the unit pixel region.

4. The image sensor of claim 2, wherein the light absorption unit is formed along the boundary between the unit pixel regions, and overlaps either end of the green color filter.

5. The image sensor of claim 4, wherein the light absorption unit comprises a red color filter material or blue color filter material.

6. The image sensor of claim 1, wherein the light absorption unit comprises:
a trench formed in the substrate;
an interface layer formed on the surface of the trench; and
a light absorbing material layer formed on the interface layer so as to gap-fill the trench.

7. An image sensor comprising:
a substrate comprising a plurality of unit pixel regions;
a color filter having a multilayer structure over the substrate; and
a light absorption unit formed in the substrate under the color filter,
wherein the color filter comprises a first color filter, a second color filter, and a third color filter, and the first to third color filters overlap the light absorption unit.

8. The image sensor of claim 7, wherein the second and third color filters are formed between the first color filter and the substrate or formed over the first color filter, and overlap both ends of the first color filter.

9. The image sensor of claim 7, wherein the light absorption unit is formed along the boundary between the unit pixel regions so as to overlap both ends of the first to third color filters.

10. A method for fabricating an image sensor, comprising:
forming a substrate including a plurality of unit pixel regions;
forming a light absorption unit in the substrate along the boundary between the unit pixel regions; and
forming a color filter over the substrate so as to correspond to each of the unit pixel regions,
wherein the color filter comprises a first color filter, a second color filter, and a third color filter.

11. The method of claim 10, wherein the first color filter comprises a green color filter, the second color filter comprises a red color filter, and the third color filter comprises a blue color filter.

12. The method of claim 11, wherein the first color filter is formed to overlap the light absorption unit.

13. The method of claim 12, wherein both ends of the first to third color filters are formed to overlap the light absorption unit.

14. The method of claim 13, wherein the forming of the light absorption unit comprises:
forming a trench along the boundary between the unit pixel regions of the substrate;
forming an interface layer along the surface of the trench; and
forming a light absorbing material layer on the interface layer so as to gap-fill the trench.
